(19) United States
(12) Patent Application Publication
(10) Pub. No.: US 2007/0007584 A1
(43) Pub. Date: Jan. 11, 2007

(54) Nitride semiconductor light emitting diode and method of manufacturing the same

(75) Inventors: Seok Min Hwang, Suwon (KR); Je Won Kim, Suwon (KR); Kun Yu Ko, Hwaseong (KR); Bok Ki Min, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/480,901

(22) Filed: Jul. 6, 2006

(30) Foreign Application Priority Data
Jul. 6, 2005 (KR) 10-2005-0060519

(51) Int. Cl. H01L 29/792

(52) U.S. Cl. 257/324

(57) ABSTRACT

The present invention relates to a GaN-based semiconductor light emitting diode and a method of manufacturing the same. The GaN-based semiconductor light emitting diode includes: a substrate; a n-type nitride semiconductor layer formed on the substrate; an active layer formed on a predetermined portion of the n-type nitride semiconductor layer; a p-type nitride semiconductor layer formed on the active layer; a transparent conductive layer formed on the p-type nitride semiconductor layer; an insulating layer formed on an upper center portion of the transparent conductive layer, the insulating layer having a contact hole defining a p-type contact region; a p-electrode formed on the insulating layer and electrically connected to the transparent conductive layer through the contact hole; and an n-electrode formed on the n-type nitride semiconductor layer where no active layer is formed.

### CROSS-REFERENCE TO RELATED APPLICATIONS

This application claims the benefit of Korean Patent Application No. 2005-0060519 filed with the Korean Intellectual Property Office on Jul. 6, 2005, the disclosure of which is incorporated herein by reference.

### BACKGROUND OF THE INVENTION

1. Field of the Invention

The present invention relates to a nitride semiconductor light emitting diode (LED) and a method of manufacturing the same. In the nitride semiconductor LED, a positive electrode and an negative electrode have a lateral structure. The luminous efficiency of the LED can be improved by optimizing the current diffusion effect.

2. Description of the Related Art

Generally, an LED is a semiconductor device to convert an electric signal into an infrared ray, a visible ray or a form of light by using a recombination of electron and hole, which is one of characteristics of a compound semiconductor.

LEDs are used in household appliances, remote controllers, electronic display boards, display devices, automatic machines, optical communications, and so on. The LEDs are classified into Infrared Emitting Diode (IRED) and Visible Light Emitting Diode (VLED).

In the LED, frequency (or wavelength) of the emitted light is a band gap function of material used in a semiconductor device. When a semiconductor material having a narrow band gap is used, photons having low energy and long wavelength are generated. On the other hand, when a semiconductor material having a wide band gap is used, photons having short wavelength are generated. Therefore, semiconductor materials of the device are selected depending on kinds of a desired light.

For example, a red LED uses AlGaInP, and a blue LED uses SiC and Group III nitride semiconductor, especially GaN. Recently, a nitride semiconductor having an empirical formula of (AlₓIn₁₋ₓ)_{y}Ga_{1-y}N (0≦x≦1, 0≦y≦1, 0≦x+y≦1) is widely used for the blue LED.

Because the nitride semiconductor LED can be grown on a sapphire substrate that is an insulation substrate, both a positive electrode (p-electrode) and an negative electrode (n-electrode) have to be formed laterally on a crystal-grown semiconductor layer. Such a conventional nitride semiconductor LED is illustrated in FIG. 1.

Referring to FIG. 1, the conventional nitride semiconductor LED includes an n-type nitride semiconductor layer 120, a Gan/InGaN active layer 130 with a multi-quantum well structure, and a p-type nitride semiconductor layer 140, which are sequentially formed on a sapphire substrate 110. Predetermined portions of the p-type nitride semiconductor layer 140 and the GaN/InGaN active layer 130 are removed by a mesa etching process, so that a predetermined portion of the n-type nitride semiconductor layer 120 is exposed.

An n-electrode 170 is formed on the n-type nitride semiconductor layer 120, and a p-electrode 160 is formed on the p-type nitride semiconductor layer 140.

Because the conventional nitride semiconductor LED has a lateral structure in which the p-electrode 160 and the n-electrode 170 are laterally formed on the semiconductor layer crystal-grown from the sapphire substrate 110, a current path becomes longer as it gets away from the n-electrode 170, so that the resistance of the n-type nitride semiconductor layer 120 increases. Therefore, a current concentratedly flows at a region adjacent to the n-electrode 170, thus degrading a current diffusion effect.

To solve these problems, a transparent conductive layer 150 is formed between the p-type nitride semiconductor layer 140 and the p-electrode 160. That is, before forming the p-electrode 160, the transparent conductive layer 150 is formed on an entire surface of the p-type nitride semiconductor layer 140. Consequently, an injection area of a current injected through the p-electrode 160 increases and thus the current diffusion effect is improved.

The conventional nitride semiconductor LED can obtain the improved current diffusion effect by further including the transparent electrode 150 between the p-type nitride semiconductor layer 140 and the p-electrode 160. However, as illustrated in FIG. 2, because the contact area between the transparent electrode 150 and the p-electrode 160 is wide, the current paths flowing from the p-electrode 160 through the transparent conductive layer 150 to the n-type nitride semiconductor layer 120 have different lengths, that is, I_{A}=R₅+R₆+R₇+R₈, I_{B}=R₆+R₇+R₈, and I_{C}=R₇+R₈, where R₁, R₂, R₃, R₄, R₅, R₆, R₇ and R₈ have the same resistance (Ω). Therefore, there is a limitation in improving an overall luminous efficiency of the LED by uniformly diffusing the current through these paths.

If the current paths I_{A}, I_{B} and I_{C} have the different lengths, the diffusion of the current is not uniform. In this case, light emitted from the emission surface is not also uniform, thus decreasing the overall luminous efficiency.

Consequently, the characteristic and reliability of the nitride semiconductor LED are degraded.

### SUMMARY OF THE INVENTION

An advantage of the present invention is that it provides a nitride semiconductor LED, in which a current applied through a p-electrode is uniformly diffused to an n-type nitride semiconductor layer through a transparent conductive layer. Therefore, the luminous efficiency of the LED can be improved.

In addition, the present invention provides a method of manufacturing the nitride semiconductor LED.

Additional aspect and advantages of the present general inventive concept will be set forth in the description which follows and, in part, will be obvious from the description, or may be learned by practice of the general inventive concept.

According to an aspect of the invention, a nitride semiconductor light emitting diode includes: a substrate; a n-type nitride semiconductor layer formed on the substrate; an active layer formed on a predetermined portion of the n-type nitride semiconductor layer; a p-type nitride semiconductor layer formed on the active layer; a transparent conductive layer formed on the p-type nitride semiconductor layer; an insulating layer formed on the upper center portion of the transparent conductive layer, the insulating layer having a contact hole defining a p-type contact region; a p-electrode formed on the insulating layer and electrically connected to the transparent conductive layer through the contact hole; and an n-electrode formed on the n-type nitride semiconductor layer where no active layer is formed.

According to another aspect of the present invention, the transparent conductive layer is partitioned into a plurality of regions by the n-electrode. Therefore, a current can be uniformly diffused to the n-electrode through the transparent conductive layer.

According to a further aspect of the present invention, the contact hole defining the p-type contact region is disposed at the center portion of the insulating layer. The contact hole is formed in a circular shape having a diameter of 1 μm to 30 μm.

According to a still further aspect of the present invention, the transparent conductive layer is formed of material selected from the group consisting of indium tin oxide (ITO), tin oxide (TO), indium zinc oxide (IZO), indium tin zinc oxide (ITZO), and transparent conductive oxide (TCO). This makes it possible for the transparent conductive layer to have the same resistance as the sheet resistance of the n-type nitride semiconductor layer. Therefore, equi-potential is formed on both ends of the PN junction, thereby improving the current diffusion.

According to a still further aspect of the present invention, a method of manufacturing a nitride semiconductor light emitting diode includes: forming an n-type nitride semiconductor layer on a substrate; forming an active layer on the n-type nitride semiconductor layer; forming a p-type nitride semiconductor layer on the active layer; performing mesa etching on the p-type nitride semiconductor layer, the active layer, and the p-type nitride semiconductor layer to expose a predetermined portion of the n-type nitride semiconductor layer; forming a transparent conductive layer on the p-type nitride semiconductor layer; forming an insulating layer having a contact hole defining a p-type contact region at the center portion of the transparent conductive layer; forming a p-electrode on the insulating layer such that the p-electrode is electrically connected to the transparent conductive layer through the contact hole; and forming an n-electrode on the exposed n-type nitride semiconductor layer.

According to a still further aspect of the present invention, the n-electrode is formed on the exposed n-type nitride semiconductor layer to partition the transparent conductive layer into a plurality of regions.

According to a still further aspect of the present invention, the contact hole defining the p-type contact region is disposed at the center portion of the insulating layer. The contact hole is formed in a circular shape having a diameter of 1 μm to 30 μm.

According to a still further aspect of the present invention, the transparent conductive layer is formed of material selected from the group consisting of indium tin oxide (ITO), tin oxide (TO), indium zinc oxide (IZO), indium tin zinc oxide (ITZO), and transparent conductive oxide (TCO).

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a sectional view of a nitride semiconductor LED according to the related art;

FIG. 2 is a circuit diagram for explaining current diffusion paths of the nitride semiconductor LED illustrated in FIG. 1;

FIG. 3 is a plan view of a nitride semiconductor LED according to an embodiment of the present invention;

FIG. 4 is a sectional view taken along line IV-IV′ of FIG. 3;

FIG. 5 is a circuit diagram for explaining current diffusion paths of the nitride semiconductor LED illustrated in FIG. 4;

FIGS. 6A to 6D are sectional views illustrating a method of manufacturing a nitride semiconductor LED according to an embodiment of the present invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a nitride semiconductor LED and a method of manufacturing the same according to the embodiments of the present invention will be described in detail with reference to the accompanying drawings.

[Structure of Nitride Semiconductor LED]

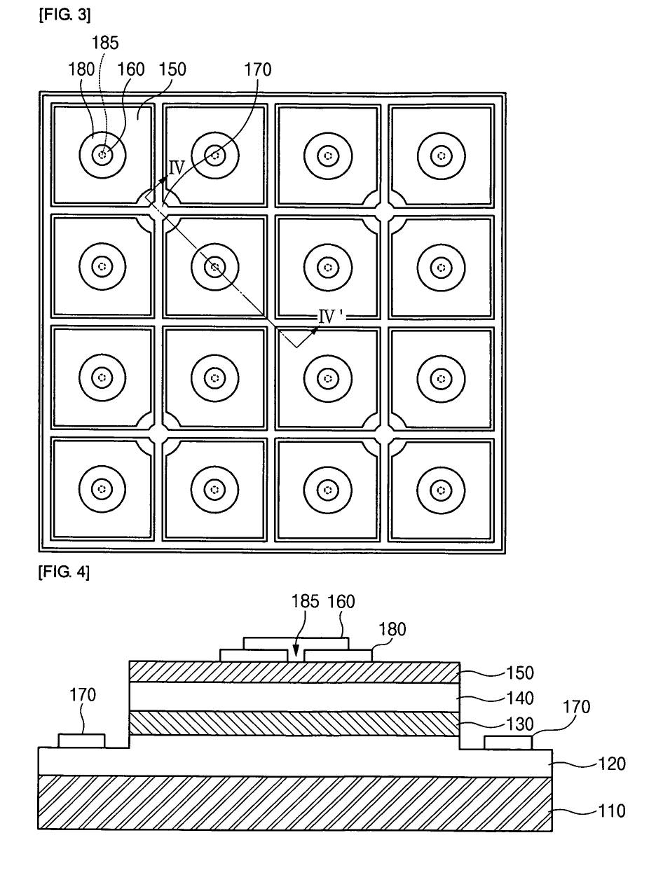

A nitride semiconductor LED according to an embodiment of the present invention will be described in detail with reference to FIGS. 3 and 4.

FIG. 3 is a plan view of a nitride semiconductor LED according to an embodiment of the present invention, and FIG. 4 is a sectional view taken along line IV-IV′ of FIG. 3.

Referring to FIGS. 3 and 4, the nitride semiconductor LED according to the embodiment of the present invention includes a light emitting structure in which an n-type nitride semiconductor layer 120, an active layer 130, and a p-type nitride semiconductor layer 140, which are sequentially formed on a light-transmissive substrate 110.

The light-transmissive substrate 110 is a substrate suitable for growing nitride semiconductor monocrystals and may be a heterogeneous substrate, such as a sapphire substrate and a SiC substrate, or a homogeneous substrate, such as a nitride substrate.

The n-type and p-type nitride semiconductor layers 120 and 140 and the active layer 130 may be formed of semiconductor material having an empirical formula of AlₓIn_{y}Ga_{(1-x-y)}N (0≦x≦1, 0≦y≦1, 0≦x+y≦1). More specifically, the n-type nitride semiconductor layer 120 may be formed of a GaN layer or a GaN/AlGaN layer in which n-type conductive impurities are doped. Further, the active layer 130 may be formed of an undoped InGaN layer having a multi-quantum well structure, and the p-type nitride semiconductor layer 140 may be formed of a GaN layer or a GaN/AlGaN layer in which p-type conductive impurities are doped. The n-type and p-type nitride semiconductor layers 120 and 140 and the active layer 130 may be grown using a Metal Organic Chemical Vapor Deposition (MOCVD) process. In this case, prior to the growth of the n-type nitride semiconductor layer 120, a buffer layer (not shown) such as AlN/GaN may be formed in advance so as to improve the lattice matching with the sapphire substrate 110.

The light emitting structure includes a plurality of mesas, an n-electrode 170, a transparent conductive layer 150, and a p-electrode 160. The mesas are formed by etching the p-type nitride semiconductor layer 140 and the active layer 130 to expose a predetermined upper portion of the n-type nitride semiconductor layer 120. The n-electrode 170 is formed on the n-type nitride semiconductor layer 120 exposed on the mesas. The transparent conductive layer 150 is formed on the p-type nitride semiconductor layer 140 so as to diffuse a current, and the p-electrode 160 acts as a reflective metal and a bonding metal on the transparent conductive layer 150.

In this light emitting structure, the transparent conductive layer 150 increases the current injection area so as to improve the current diffusion effect. Preferably, the transparent conductive layer 150 is formed of material selected from the group consisting of indium tin oxide (ITO), tin oxide (TO), indium zinc oxide (IZO), indium tin zinc oxide (ITZO), and transparent conductive oxide (TCO). This makes it possible for the transparent conductive layer 150 to have the same resistance as the sheet resistance of the n-type nitride semiconductor layer 120, so that both ends of the PN junction form equipotential. Consequently, the current diffusion effect can be further improved. In addition, it is preferable that the transparent conductive layer 150 be partitioned into a plurality of regions by the n-electrode 170. Therefore, the current can be transferred more uniformly to the n-electrode 170 through the transparent conductive layer 150, thus improving the current diffusion effect much more.

Meanwhile, the nitride semiconductor LED according to the embodiment of the present invention includes an insulating layer 180 having a contact hole 185 defining a p-type contact region between the transparent conductive layer 150 and the p-electrode 160. At this point, the contact hole 185 exposes a predetermined portion of the transparent conductive layer 150 thereunder, and the p-electrode 160 is electrically connected to the transparent conductive layer 150 through the contact hole 185.

More specifically, the insulating layer 180 is disposed at the upper center portion of the transparent conductive layer 150, and the contact hole 185 is disposed at the center portion of the insulating layer 180 to expose a predetermined portion of the transparent conductive layer 150 disposed under the insulating layer 180.

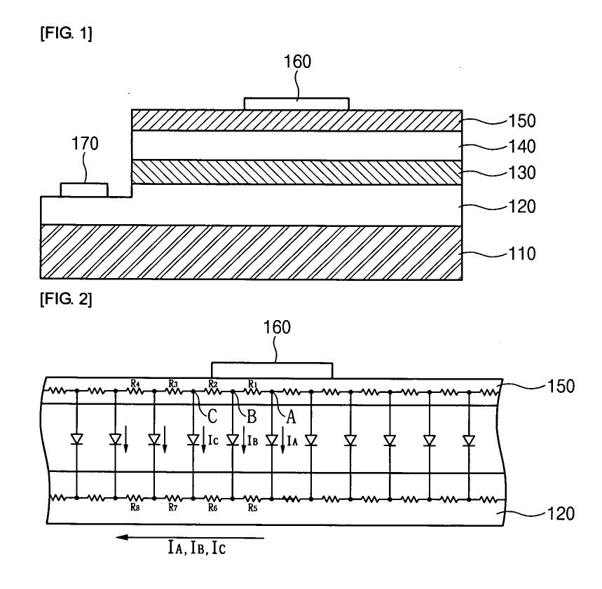

In the nitride semiconductor LED according to the embodiment of the present invention, the p-electrode 160 and the transparent conductive layer 150 are contacted with each other only through the contact hole 185 of the insulating layer 180 formed between the p-electrode 160 and the transparent conductive layer 150. Therefore, compared with the conventional nitride semiconductor LED (see FIG. 1), the contact area between the p-electrode 160 and the transparent conductive layer 150 can be minimized.

The contact hole 185 is formed in a circular shape having a diameter of 1 μm to 30 μm, which is close to an almost ideal point, so as to further minimize the contact area between the p-electrode 160 and the transparent conductive layer 150 and maintain the constant distance between the contact hole 185 and its adjacent region. As the diameter of the contact hole 185 is smaller, the contact area between the p-electrode 160 and the transparent conductive layer 150 can be further minimized. However, when the contact hole 185 has the diameter less than 1 μm, the contact hole 185 does not play its own role. Further, when the contact area becomes small, its resistance increases. For this reason, the contact hole 185 is formed in the circular shape having the diameter of 1 μm to 30 μm.

As described above, if the contact area between the p-electrode 160 and the transparent conductive layer 150 is minimized through the contact hole 185 formed in the center portion of the transparent conductive layer 150, the problem of the related art can be solved. That is, the present invention can solve the non-uniform current diffusion that is caused when the current paths I_{A}, I_{B} and I_{C} flowing from the p-electrode 160 through the transparent conductive layer 150 to the n-type nitride semiconductor layer 120 have the different lengths because of the wide contact area between the p-electrode 160 and the transparent conductive layer 150.

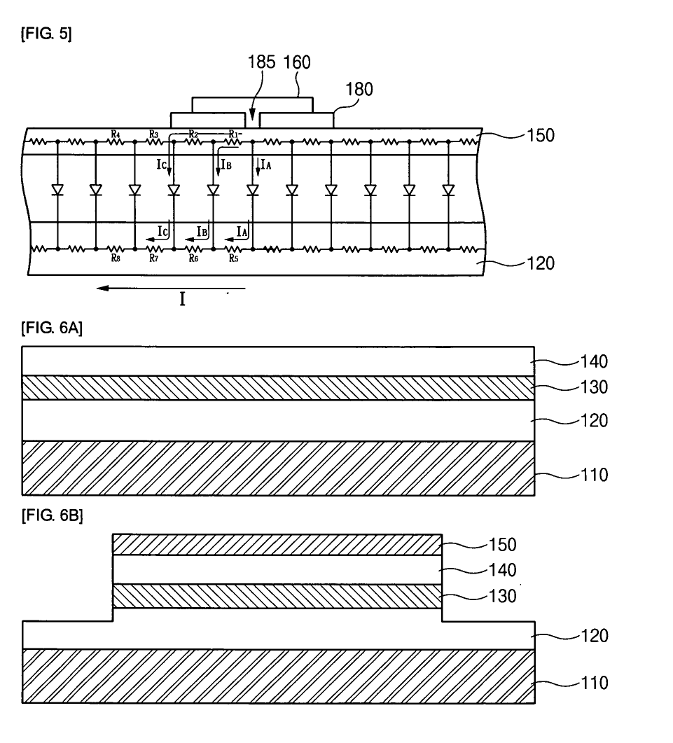

More specifically, as illustrated in FIG. 5, the current paths flowing from the p-electrode 160 through the transparent conductive layer 150 to the n-type nitride semiconductor layer 120 have the same length because of the narrow contact area between the transparent conductive layer 150 and the p-electrode 160. That is, I_{A}=R₅+R₆+R₇+R₈, I_{B}=R₁+R₆+R₇+R₈, and I_{C}=R₁+R₂+R₇+R₈, where R₁, R₂, R₃, R₄, R₅, R₆, R₇ and R₈ have the same resistance (Ω). Therefore, the present invention can improve the overall luminous efficiency of the LED by uniformly diffusing the current through these paths.

[Method of Manufacturing Nitride Semiconductor LED]

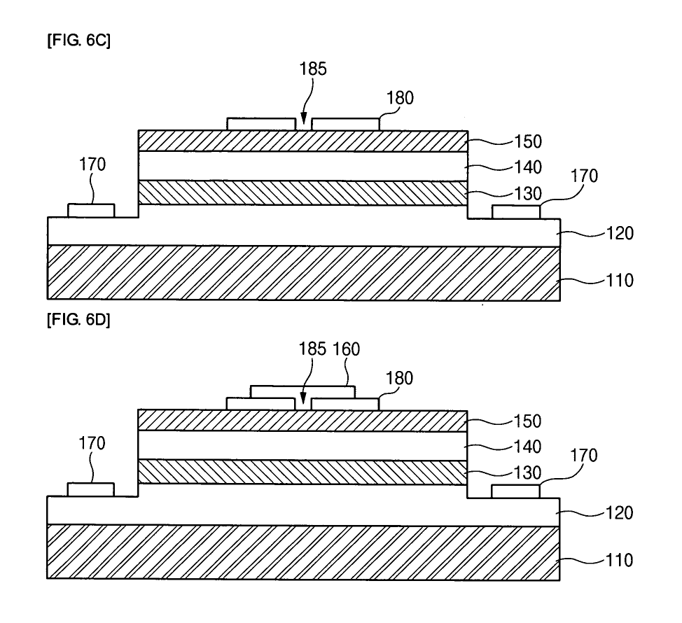

Hereinafter, a method of manufacturing a nitride semiconductor LED according to an embodiment of the present invention will be described in detail with reference to FIGS. 6A to 6D.

FIGS. 6A to 6D are sectional views illustrating a method of manufacturing a nitride semiconductor LED according to an embodiment of the present invention.

Referring to FIG. 6A, a light emitting structure is formed by sequentially stacking an n-type nitride semiconductor layer 120, an active layer 130, and a p-type nitride semiconductor layer 140 on a substrate 110. The substrate 110 is a substrate suitable for growing nitride semiconductor monocrystals and may be a heterogeneous substrate, such as a sapphire substrate and a SiC substrate, or a homogeneous substrate, such as a nitride substrate. Also, the n-type and p-type nitride semiconductor layers 120 and 140 and the active layer 130 may be formed of semiconductor material having an empirical formula of AlₓIn_{y}Ga_{(1-x-y)}N (0≦x≦1, 0≦y≦1, 0≦x+y≦1). The n-type and p-type nitride semiconductor layers 120 and 140 and the active layer 130 may be formed using a known nitride deposition process such as MOCVD or MBE process.

Meanwhile, prior to the growth of the n-type nitride semiconductor layer 120, a buffer layer (not shown) such as AlN/GaN may be formed in advance so as to improve the lattice matching with the sapphire substrate 110.

Referring to FIG. 6B, a mesa etching process is performed to remove predetermined portions of the p-type nitride semiconductor layer 140 and the active layer 130, thereby exposing a predetermined portion of the n-type nitride semiconductor layer 120.

Thereafter, a transparent conductive layer 150 is formed on the p-type nitride semiconductor layer 140 so as to increase the current injection area and improve the current diffusion effect. Preferably, the transparent conductive layer 150 is formed of material having the same resistance as the sheet resistance of the n-type nitride semiconductor layer 120. More specifically, the transparent conductive layer 150 may be formed of material selected from the group consisting of indium tin oxide (ITO), tin oxide (TO), indium zinc oxide (IZO), indium tin zinc oxide (ITZO), and transparent conductive oxide (TCO). Consequently, the current diffusion effect can be further improved because the equipotential is formed on both ends of the PN junction, that is, the transparent conductive layer 150 and the n-type nitride semiconductor layer 120.

Referring to FIG. 6C, an insulating layer 180 having a contact hole 185 defining a p-type contact region is formed in the upper center portion of the transparent conductive layer 150. At this point, the contact hole 185 is formed at the center portion of the insulating layer 180. That is, the paths of the diffused currents can be uniform centering on the contact hole 185 by disposing the contact hole 185 at the center portion of the transparent conductive layer 150 so as to increase the current injection area and improve the current diffusion effect. In this embodiment, it is preferable that the contact hole 185 be formed in a circular shape having a diameter of 1 μm to 30 μm, which is close to an almost ideal point, so as to make the paths of the diffused currents be more uniform. The insulating layer 180 may be formed of an insulating material, such as SiO₂, Si₃N₄, and Al₂O₃.

Referring to FIG. 6D, an n-electrode 170 is formed on the n-type nitride semiconductor layer 120 exposed by the mesa etching process, and a p-electrode 160 is formed on the insulating layer 180 having the contact hole 185. At this point, the p-electrode 160 is electrically connected to the transparent conductive layer 150 through the contact hole 185. In addition, it is preferable that the n-electrode 170 be formed to partition the transparent conductive layer 150 into a plurality of regions.

As described above, in the nitride semiconductor LED, the current diffusion paths flowing from the p-electrode through the transparent conductive layer to the n-type nitride semiconductor layer are maximally uniform as a whole, thereby remarkably improving the overall luminous efficiency.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A nitride semiconductor light emitting diode comprising:
a substrate;
a n-type nitride semiconductor layer that is formed on the substrate;
an active layer that is formed on a predetermined portion of the n-type nitride semiconductor layer;
a p-type nitride semiconductor layer that is formed on the active layer;
a transparent conductive layer that is formed on the p-type nitride semiconductor layer;
an insulating layer that is formed on the upper center portion of the transparent conductive layer, the insulating layer having a contact hole defining a p-type contact region;
a p-electrode that is formed on the insulating layer and is electrically connected to the transparent conductive layer through the contact hole; and
an n-electrode that is formed on the n-type nitride semiconductor layer where no active layer is formed.

2. The nitride semiconductor light emitting diode according to claim 1,
wherein the transparent conductive layer is partitioned into a plurality of regions by the n-electrode.

3. The nitride semiconductor light emitting diode according to claim 1,
wherein the contact hole defining the p-type contact region is disposed at the center portion of the insulating layer.

4. The nitride semiconductor light emitting diode according to claim 1,
wherein the contact hole has a diameter of 1 μm to 30 μm.

5. The nitride semiconductor light emitting diode according to claim 1,
wherein the contact hole is formed in a circular shape.

6. The nitride semiconductor light emitting diode according to claim 1,
wherein the transparent conductive layer is formed of material selected from the group consisting of indium tin oxide (ITO), tin oxide (TO), indium zinc oxide (IZO), indium tin zinc oxide (ITZO), and transparent conductive oxide (TCO).

7. A method of manufacturing a nitride semiconductor light emitting diode, comprising:
forming an n-type nitride semiconductor layer on a substrate;
forming an active layer on the n-type nitride semiconductor layer;
forming a p-type nitride semiconductor layer on the active layer;
performing mesa etching on the p-type nitride semiconductor layer, the active layer, and the p-type nitride semiconductor layer to expose a predetermined portion of the n-type nitride semiconductor layer;
forming a transparent conductive layer on the p-type nitride semiconductor layer;
forming an insulating layer having a contact hole defining a p-type contact region at the center portion of the transparent conductive layer;
forming a p-electrode on the insulating layer such that the p-electrode is electrically connected to the transparent conductive layer through the contact hole; and
forming an n-electrode on the exposed n-type nitride semiconductor layer.

8. The method according to claim 7,
wherein the n-electrode is formed on the exposed n-type nitride semiconductor layer to partition the transparent conductive layer into a plurality of regions.

9. The method according to claim 7,
wherein the contact hole defining the p-type contact region is disposed at the center portion of the insulating layer.

10. The method according to claim 7,
wherein the contact hole has a diameter of 1 μm to 30 μm.

11. The method according to claim 7,
wherein the contact hole is formed in a circular shape.

12. The method according to claim 7,
wherein the transparent conductive layer is formed of material selected from the group consisting of indium tin oxide (ITO), tin oxide (TO), indium zinc oxide (IZO), indium tin zinc oxide (ITZO), and transparent conductive oxide (TCO).
